(19) United States
(12) Patent Application Publication
(10) Pub. No.: US 2025/0323076 A1
(43) Pub. Date: Oct. 16, 2025

(54) TRANSPORT CONTAINER FOR SEMICONDUCTOR WAFER AND METHOD OF MANUFACTURING SEMICONDUCTOR ELEMENT

(71) Applicant: Mitsubishi Electric Corporation, Tokyo (JP)

(72) Inventors: Shotaro NAKAMURA, Tokyo (JP); Kazuaki MIKAMI, Tokyo (JP); Tsuyoshi TSUCHIYA, Tokyo (JP); Satoshi YASUI, Tokyo (JP); Yasuo KONISHI, Tokyo (JP)

(73) Assignee: Mitsubishi Electric Corporation, Tokyo (JP)

(21) Appl. No.: 19/056,683

(22) Filed: Feb. 18, 2025

(30) Foreign Application Priority Data
Apr. 16, 2024 (JP) 2024-066361

(51) Int. Cl. H01L 21/673

(52) U.S. Cl. CPC H01L 21/67373; H01L 21/67376; H01L 21/67383; H01L 21/67386

(57) ABSTRACT

A transport container includes a housing having an opening through which the semiconductor wafer can be taken in and out from the Y-direction, a pair of thresholds disposed in the housing and supporting the back surface of the circumferential edge portion of the semiconductor wafer in the −X-direction and the X-direction, a lid capable of opening and closing the opening, and a retainer fixed to the inner surface of the lid and holding the end face of the semiconductor wafer in the Y-direction. The retainer includes a fixing portion fixed to the inner surface of the lid, and a left-wing portion and a right-wing portion respectively extending from the fixing portion to the left and right and having elastic force, and the left-wing portion and the right-wing portion hold the end face of the semiconductor wafer by the elastic force.

### BACKGROUND OF THE INVENTION

### Field of the Invention

The present disclosure relates to a transport container for a semiconductor wafer and a method of manufacturing a semiconductor element.

### Description of the Background Art

In a conventional transport container for a semiconductor wafer, the diameter of a semiconductor wafer to be stored is uniformly determined (for example, a diameter of 450 mm), and a retainer for holding both sides of a front circumferential edge of the semiconductor wafer is specialized for the semiconductor wafer of that size (for example, see Japanese Patent Application Laid-Open No. 2011-108715).

In the technique described in Japanese Patent Application Laid-Open No. 2011-108715, it is proposed that for a semiconductor wafer having a sufficiently large thickness and a diameter of, for example, 450 mm, the semiconductor wafer being easily deflected by its own weight is held with high dimensional accuracy in a substrate-storing container (corresponding to a transport container).

However, the technique described in Japanese Patent Application Laid-Open No. 2011-108715 has not considered uniformly holding a semiconductor wafer thinned to several 100 μm in thickness and a semiconductor wafer having different diameters.

### SUMMARY

An object of the present disclosure is to provide a technique capable of uniformly holding a thinned semiconductor wafer and semiconductor wafers having different diameters.

A transport container for a semiconductor wafer according to the present disclosure includes a housing, a pair of thresholds, a lid, and a retainer. The housing has an opening through which a semiconductor wafer can be taken in and out from a first direction. The pair of thresholds is disposed in the housing, and supports a back surface of a circumferential edge portion of the semiconductor wafer in a second direction intersecting the first direction and a third direction opposite to the second direction. The lid is capable of opening and closing the opening. The retainer is fixed to an inner surface of the lid, and holds an end face of the semiconductor wafer in the first direction. The retainer includes a fixing portion fixed to the inner surface of the lid, and a left-wing portion and a right-wing portion respectively extending to left and right from the fixing portion and having elastic force. The left-wing portion and the right-wing portion hold the end face of the semiconductor wafer by the elastic force.

In a state where the back surface of the circumferential edge portion of the semiconductor wafer is supported by the pair of thresholds, applying force in a direction toward the center of the semiconductor wafer by the left-wing portion and the right-wing portion to hold the semiconductor wafer makes it possible to apply force in a direction toward the center of the semiconductor wafer to hold even the thinned semiconductor wafer and the semiconductor wafer having a smaller diameter. Therefore, the thinned semiconductor wafer and the semiconductor wafers having different diameters can be uniformly held.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view of a transport container according to a first preferred embodiment;

FIG. 2 is an enlarged top view of a retainer and its periphery included in the transport container according to the first preferred embodiment;

FIG. 3 is an enlarged top view showing an example of the retainer and its periphery when the distance from the fixing portion of the retainer to the end face of the semiconductor wafer is 10 mm;

FIG. 4 is an enlarged top view showing another example of the retainer and its periphery when the distance from the fixing portion of the retainer to the end face of the semiconductor wafer is 10 mm;

FIG. 5 is an enlarged top view of the retainer and its periphery when the left-wing portion and the right-wing portion of the retainer hold the semiconductor wafer in surface contact;

FIG. 6 is an enlarged top view showing a positional relationship among the semiconductor wafers having respective diameters stored in the transport container;

FIG. 7 is a graph showing the relationship between the diameter of the semiconductor wafer and the force for holding the semiconductor wafer;

FIG. 8 is an enlarged top view showing a state in which the semiconductor wafers having a diameter of 200 mm and a diameter of 300 mm is held by the retainer;

FIGS. 9A to 9I are cross-sectional views showing a method of manufacturing a semiconductor element;

FIG. 10 is a flowchart showing a method of manufacturing a semiconductor element;

FIG. 11 is an enlarged top view of a retainer included in a transport container according to a second preferred embodiment;

FIG. 12 is a view of a retainer included in a transport container according to a third preferred embodiment as viewed from the −Y-direction;

FIG. 13 is a cross-sectional view of the left-wing portion of the retainer and its periphery; and

FIG. 14 is a view of a retainer included in a transport container according to a fourth preferred embodiment as viewed from the −Y-direction.

### DESCRIPTION OF THE PREFERRED EMBODIMENTS

### First Preferred Embodiment

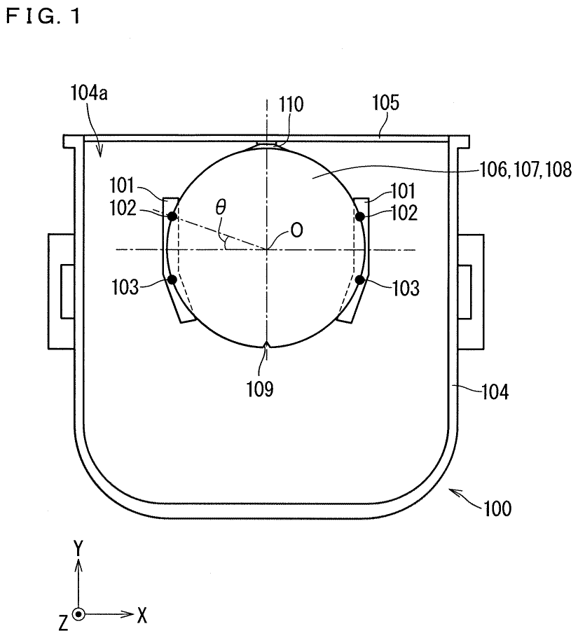

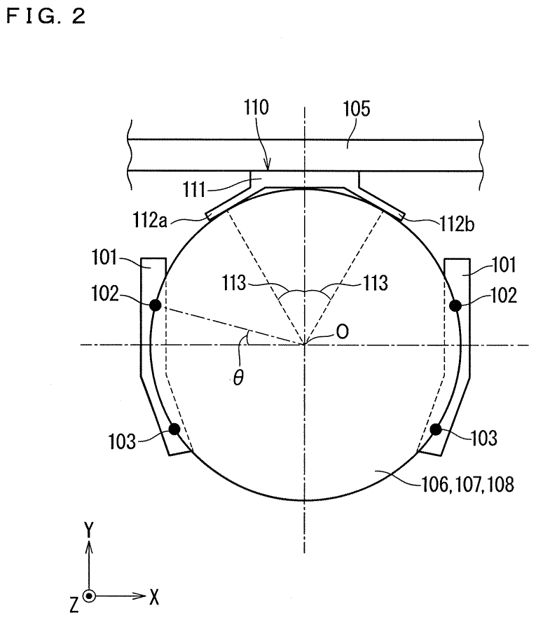

A first preferred embodiment will be described below with reference to the drawings. FIG. 1 is a top view of a transport container 100 according to the first preferred embodiment. FIG. 2 is an enlarged top view of a retainer 110 and its periphery included in the transport container 100 according to the first preferred embodiment.

In FIG. 1, an X-direction, a Y-direction, and a Z-direction are orthogonal to one another. The X-direction, Y-direction, and Z-direction shown in the following drawings are also orthogonal to one another. Hereinafter, a direction including the X-direction and the −X-direction that is a direction opposite to the X-direction is also referred to as “X-axis direction”. In addition, hereinafter, a direction including the Y-direction and the −Y-direction that is a direction opposite to the Y-direction is also referred to as “Y-axis direction”. In addition, hereinafter, a direction including the Z-direction and the −Z-direction that is a direction opposite to the Z-direction is also referred to as “Z-axis direction”.

### <Configuration of Transport Container>

As shown in FIG. 1, the transport container 100 is a transport container capable in of storing, for example, up to 25 semiconductor wafers 106, 107, and 108 having diameters different from each other. For example, let the diameter of the semiconductor wafer 106 be 200 mm, let the diameter of the semiconductor wafer 107 be 199 mm or more and 200 mm or less, and let the diameter of the semiconductor wafer 108 be 198 mm or more and 199 mm or less. In addition, the semiconductor wafer 107 or 108 is thinned with respect to the semiconductor wafer 106.

It should be noted that the semiconductor wafer stored in the transport container 100 may be only the semiconductor wafer 106 having a diameter of 200 mm, may be only the semiconductor wafer 107 having a diameter of 199 mm or more and 200 mm or less, or may be only the semiconductor wafer 108 having a diameter of 198 mm or more and 199 mm or less. Alternatively, the semiconductor wafers 106, 107, and 108 having diameters different from each other may be mixed.

The transport container 100 includes a housing 104 that is a box-shaped container, a pair of thresholds 101, a lid 105, and a retainer 110.

The housing 104 has an opening 104a through which the semiconductor wafer 106, 107, or 108 can be taken in and out from the Y direction (first direction).

The pair of thresholds 101 is disposed in the housing 104 and supports the back surfaces of the circumferential edge portions of the semiconductor wafer 106, 107, or 108 in the −X-direction (second direction) intersecting the Y-direction and the X-direction (third direction) opposite to the −X-direction. More specifically, fulcrums 102 and 103 are provided at intervals on both the pair of thresholds 101, and the fulcrums 102 and 103 hold the back surfaces of the circumferential edge portions of the semiconductor wafer 106, 107, or 108. The pair of thresholds 101 is formed in L shapes in a top view (as viewed from the Z-direction), but may be formed in I shapes.

The lid 105 is attached to the housing 104 so as to be able to open and close the opening 104a of the housing 104. The retainer 110 is fixed to a central portion of the inner surface of the lid 105. The retainer 110 holds the end face of the semiconductor wafer 106, 107, or 108 in a state where the lid 105 is closed.

It should be noted that the semiconductor wafer 106, 107, or 108 is stored so that the notch 109 faces the opposite side (−Y direction) from the opening 104a, but may face in any direction. In addition, when the semiconductor wafers 106, 107, and 108 are stored in the transport container 100 by a semiconductor manufacturing apparatus (not shown), the notches 109 of the semiconductor wafers 106, 107, and 108 do not need to be oriented in the same direction.

Next, details of the retainer 110 will be described. As shown in FIG. 2, the retainer 110 includes a fixing portion 111 fixed to the inner surface of the lid 105, and a left-wing portion 112a and a right-wing portion 112b respectively extending in the left and right directions (X-axis direction) from the fixing portion 111. Since the fixing portion 111 is configured to be detachable from the inner surface of the lid 105 by, for example, fitting or the like, the retainer 110 is detachable from the lid 105. In addition, the fixing portion 111 and the left-wing portion 112a and right-wing portion 112b may be an integral body or separate bodies. In the case of separate bodies, the left-wing portion 112a and the right-wing portion 112b are also detachable from the fixing portion 111. The left-wing portion 112a and the right-wing portion 112b are made, for example, of a resin plate having elastic force, and hold the end face (more specifically, the end face in the Y-direction) of the semiconductor wafer 106, 107, or 108 by elastic force. It should be noted that the left-wing portion 112a and the right-wing portion 112b may be made of a metal plate having elastic force. In addition, the left-wing portion 112a and the right-wing portion 112b are formed symmetrically and are formed in a size capable of holding up to 25 semiconductor wafers 106, 107, or 108 along the vertical direction (Z-axis direction).

The angle 113 is an angle formed between a perpendicular line extending from the center O of the semiconductor wafer 106, 107, or 108 to the fixing portion 111 and a line from a contact point where the retainer 110 and the semiconductor wafer 106, 107, or 108 are in contact with each other toward the center O of the semiconductor wafer 106, 107, or 108. The left-wing portion 112a and the right-wing portion 112b hold the semiconductor wafer 106, 107, or 108 in point contact.

In addition, when an angle formed between a perpendicular line extending from the center O of the semiconductor wafer 106, 107, or 108 to the pair of thresholds 101 and a line from the fulcrum 102 of the pair of thresholds 101 toward the center O of the semiconductor wafer 106, 107, or 108 is θ, the angle 113 can also be defined as 90-θ degrees, and the maximum value of the angle 113 is about 80 degrees. On the other hand, in order to apply force in the direction toward the center O of the semiconductor wafer 106, 107, or 108, the angle 113 needs to be larger than 0 degrees.

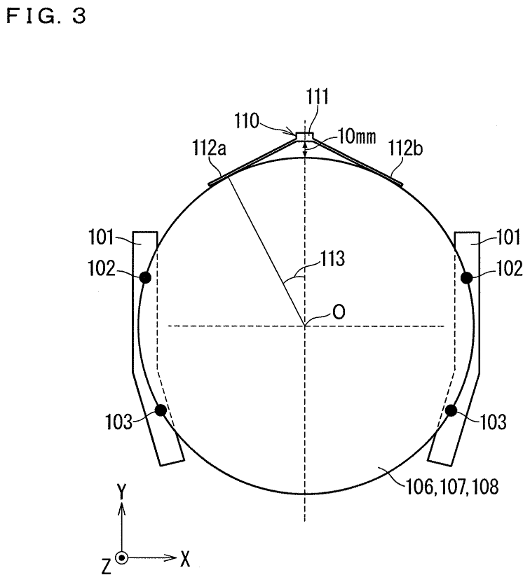

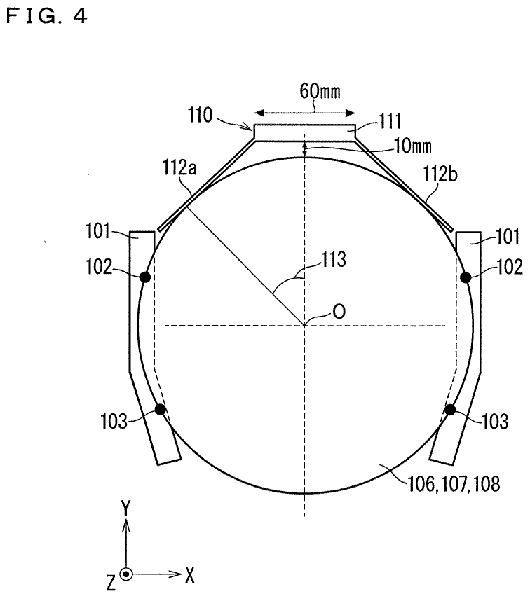

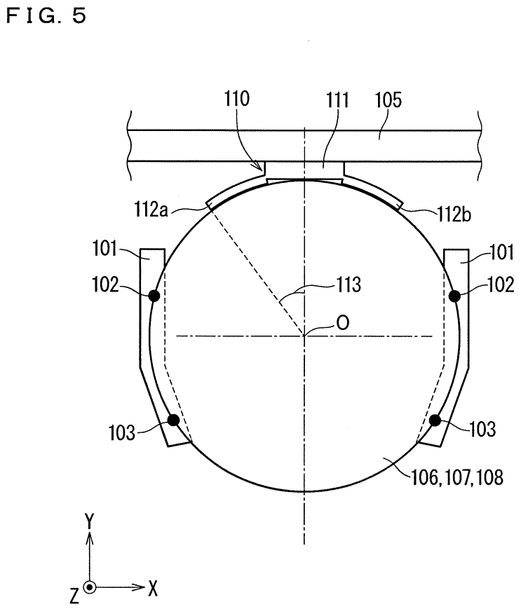

FIG. 3 is an enlarged top view showing an example of the retainer 110 and its periphery when the distance from the fixing portion 111 of the retainer 110 to the end face of the semiconductor wafer 106, 107, or 108 is 10 mm. FIG. 4 is an enlarged top view showing another example of the retainer 110 and its periphery when the distance from the fixing portion 111 of the retainer 110 to the end face of the semiconductor wafer 106, 107, or 108 is 10 mm. FIG. 5 is an enlarged top view of the retainer 110 and its periphery when the left-wing portion 112a and the right-wing portion 112b of the retainer 110 hold the semiconductor wafer 106, 107, or 108 in surface contact.

As shown in FIG. 3, for example, when the distance from the fixing portion 111 of the retainer 110 to the end face of the semiconductor wafer 106, 107, or 108 is 10 mm, if the left-wing portion 112a and the right-wing portion 112b respectively extend from the left and right end portions of the fixing portion 111, the angle 113 is about 30 degrees. For example, when the semiconductor wafer 106, 107, or 108 is held at an angle smaller than the angle 113, the distance from the fixing portion 111 to the semiconductor wafer 106, 107, or 108 needs to be reduced, and the thickness of the fixing portion 111 also needs to be increased.

On the other hand, as shown in FIG. 4, for example, when the angle 113 is about 45 degrees, when the distance from the fixing portion 111 of the retainer 110 to the end face of the semiconductor wafer 106, 107, or 108 is 10 mm, the length of the fixing portion 111 in the X-axis direction is about 60 mm. The angle 113 is desirable because holding an angle at 45 degrees distributes the force evenly and is most stable, but the angle 113 is not limited thereto as long as holding an angle at another angle is stable. When it is desired to perform pressing at 45 degrees or more, the length in the X-axis direction of the fixing portion 111 needs to be longer than 60 mm.

Alternatively, as shown in FIG. 5, the surfaces on the side holding the semiconductor wafer 106, 107, or 108 in the left-wing portion 112a and the right-wing portion 112b may be formed so as to draw an arc having the same curvature as the end face of the semiconductor wafer 106, 107, or 108, and the entire surfaces on the side holding the semiconductor wafer 106, 107, or 108 in the left-wing portion 112a and the right-wing portion 112b may be in contact with the end face of the semiconductor wafer 106, 107, or 108. Let the angle 113 in this case be larger than 0 degrees and equal to or smaller than 80 degrees as in the case of point contact. Not only the surface contact but also the mixture of the surface contact and the point contact may be used, but using only the surface contact increases the area to be held, and thus the holding force is more stable.

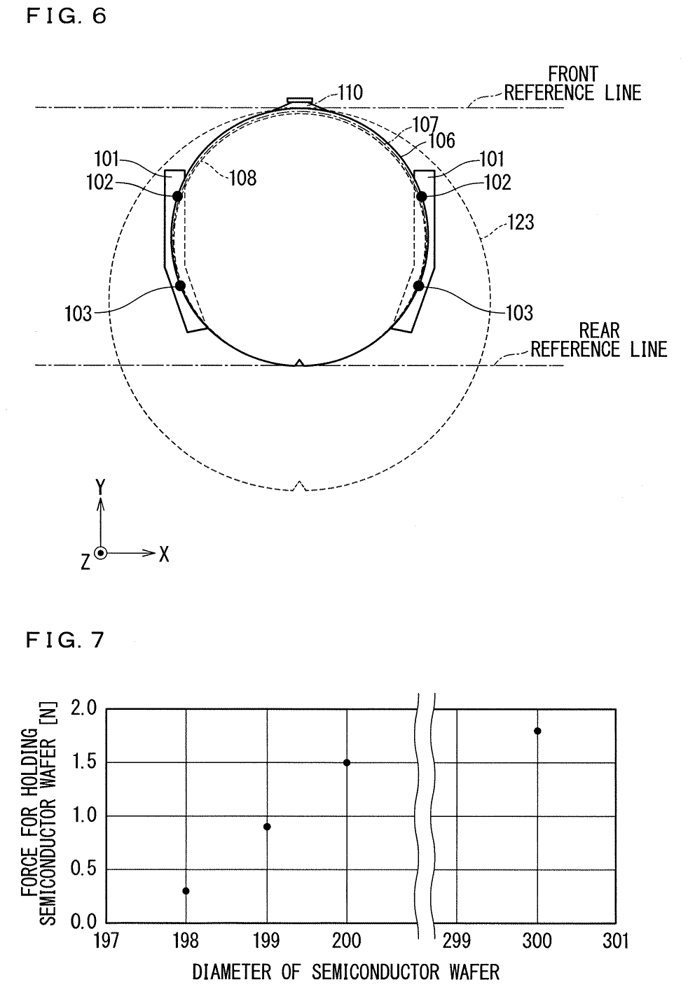

FIG. 6 is an enlarged top view showing a positional relationship among the semiconductor wafers 106, 107, 108, and 123 having respective diameters stored in the transport container 100. As shown in FIG. 6, the semiconductor wafer 123 having a diameter of 300 mm and the semiconductor wafer 106 having a diameter of 200 mm are stored so as to be in contact with the front reference line. Although not shown, when the semiconductor wafer 123 is stored, the pair of thresholds 101 is arranged at positions capable of supporting the back surfaces of the circumferential edge portions of the semiconductor wafer 123. On the other hand, the semiconductor wafer 107 having a diameter of 199 mm or more and 200 mm or less, and the semiconductor wafer 108 having a diameter of 198 mm or more and 199 mm or less are pushed in by the retainer 110 so that the end face on the −Y side is positioned at the rear reference line.

FIG. 7 is a graph showing the relationship between the diameter of the semiconductor wafer and the force for holding the semiconductor wafer. As shown in FIG. 7, when the diameter of the semiconductor wafer changes, the force for holding the semiconductor wafer, that is, the holding force for holding the semiconductor wafer changes. The holding force at the time of holding the thinned semiconductor wafer only needs to be in a range of more than 0 N and 2 N or less, and for example, when a spring constant is selected such as to press the semiconductor wafer 107 having a diameter of 199 mm or more and 200 mm or less with about 1 N, it is possible to cope with semiconductor wafers having different diameters.

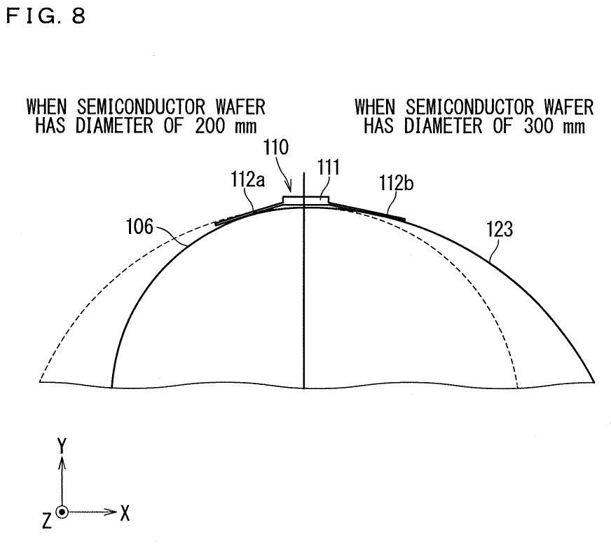

FIG. 8 is an enlarged top view showing a state in which the semiconductor wafers 106 and 123 having a diameter of 200 mm and a diameter of 300 mm is held by the retainer 110. The left part of FIG. 8 shows a state in which the semiconductor wafer 106 having a diameter of 200 mm is held, and the right part of FIG. 8 shows a state in which the semiconductor wafer 123 having a diameter of 300 mm is held.

As shown in FIG. 8, it is possible to hold not only the semiconductor wafer 106 having a diameter of 200 mm but also the semiconductor wafer 123 having a diameter of 300 mm. As compared with the case of holding the semiconductor wafer 106 having a diameter of 200 mm, as the diameter of the semiconductor wafer 123 increases, the angle 113 (see FIG. 2) changes to the acute angle side, and the holding force changes in the direction of increasing, but both fall within the above range.

### <Method of Manufacturing Semiconductor Element>

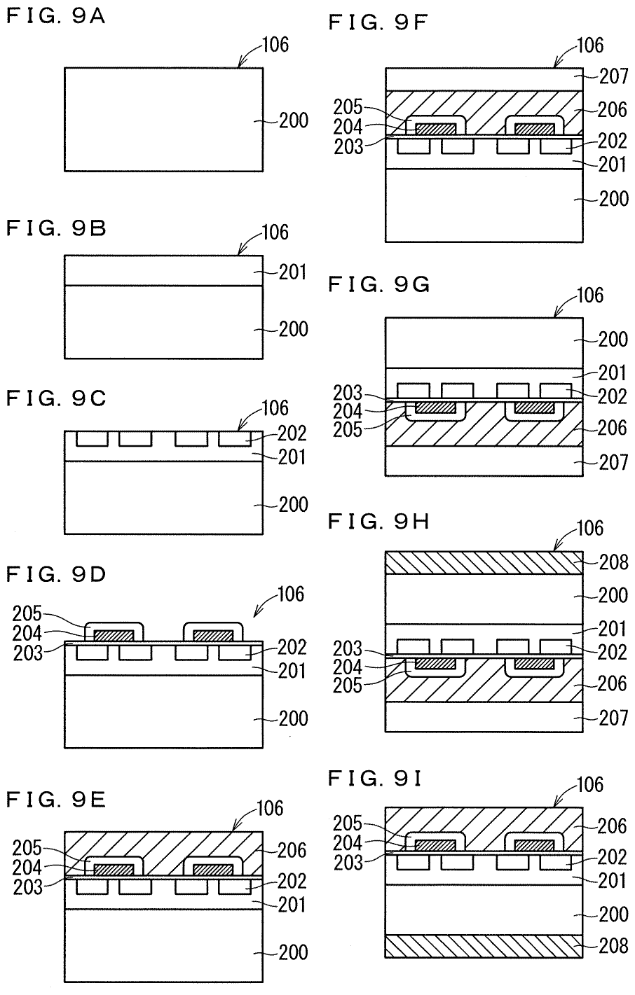

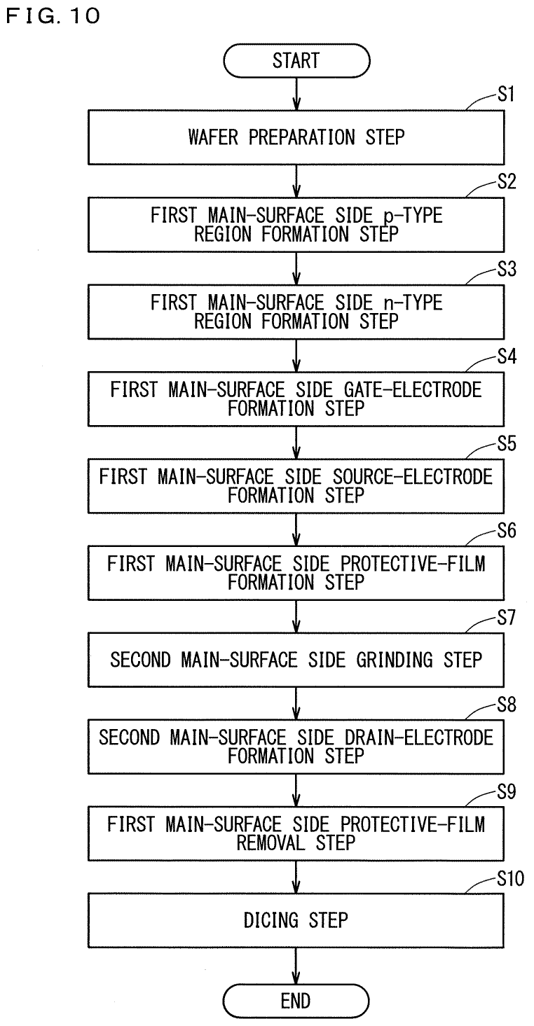

Next, a method of manufacturing a semiconductor element using the transport container 100 will be described. FIGS. 9A to 9I are cross-sectional views showing a method of manufacturing a semiconductor element. FIG. 10 is a flowchart showing a method of manufacturing a semiconductor element.

A method of manufacturing a metal oxide semiconductor field effect transistor (MOSFET) as a semiconductor element will be taken as an example. In the following description of the manufacturing method, the method of manufacturing the active region of the MOSFET is described, and the termination region, the gate signal reception region, and the like are omitted. Although the MOSFET is described by taking a planar type as an example, the MOSFET may be a trench type MOSFET or a semiconductor element other than the MOSFET.

As shown in FIG. 10, the method of manufacturing a semiconductor element includes: a wafer preparation step (step S1), a first main-surface side p-type region formation step (step S2), a first main-surface side n-type region formation step (step S3), a first main-surface side gate-electrode formation step (step S4), a first main-surface side source-electrode formation step (step S5), a first main-surface side protective-film formation step (step S6), a second main-surface side grinding step (step S7), a second main-surface side drain-electrode formation step (step S8), a first main-surface side protective-film removal step (step S9), and a dicing step (step S10). It should be noted that it is desirable to use the transport container 100 in steps S1 to S10, but for example, in the dicing step (step S10), it is necessary to transfer the semiconductor wafer to a dedicated carrier, and thus the transport container 100 does not need to be used.

In the following, each step will be described. Here, a case of manufacturing a semiconductor element from the semiconductor wafer 106 will be described. As shown in FIGS. 9A and 10, in the wafer preparation step (step S1), a plurality of semiconductor wafers 106 to be the n-type drift layer 200 are prepared. It is conceivable that the material of the semiconductor wafer 106 is Si, SiC, GaO₂, or the like. In the following steps, what is referred to as the semiconductor wafer 106 also includes a state in which another semiconductor layer or electrode is formed in the drift layer.

As shown in FIGS. 9B and 10, the first main-surface side p-type region formation step (step S2) includes an ion implantation step and a heating step. In the ion implantation step, donors are ion-implanted into the first main-surface side of the semiconductor wafer 106. As the donor, for example, boron or aluminum is used. In the heating step, heating the semiconductor wafer 106 electrically activates donors to form the p-type region 201.

As shown in FIGS. 9C and 10, the first main-surface side n-type region formation step (step S3) includes an exposure step, an etching step, an ion implantation step, and a heating step. In the exposure step, the photoresist is applied to the first main-surface side of the semiconductor wafer 106 so as to have a uniform thickness. The photoresist may be either photosensitive or non-photosensitive. Then, a shot pattern is formed on the photoresist film from the first main-surface side of the semiconductor wafer 106 using a photomask. In the etching step, the photoresist film is locally removed by performing dry etching or wet etching processing on the semiconductor wafer 106. In the ion implantation step, acceptors are ion-implanted from the first main-surface side of the semiconductor wafer 106. As the acceptor, for example, nitrogen, phosphorus, or the like is used. In the heating step, heating the semiconductor wafer 106 electrically activates the acceptor ion to form the n-type region 202 on the first main-surface side.

As shown in FIGS. 9D and 10, the first main-surface side gate-electrode formation step (step S4) includes an oxide film formation step, a polysilicon deposition step, an exposure step, an etching step, and an oxide film formation step. In the oxide film formation step, the semiconductor wafer 106 is heated in an atmosphere containing oxygen to form an oxide film 203. In the polysilicon deposition step, polysilicon doped with n-type or p-type impurities is deposited by chemical vapor deposition (CVD) or the like to form a gate electrode. In the exposure step, the photoresist is applied to the first main-surface side of the semiconductor wafer 106 so as to have a uniform thickness. The photoresist may be either photosensitive or non-photosensitive. Then, a shot pattern is formed on the photoresist film from the first main-surface side of the semiconductor wafer 106 using a photomask. In the etching step, the photoresist film is locally removed by performing dry etching or wet etching processing on the semiconductor wafer 106, and a gate electrode 204 is formed. In the oxide film formation step, the semiconductor wafer 106 is heated in an atmosphere containing oxygen to form an oxide film 205.

As shown in FIGS. 9E and 10, in the first main-surface side source-electrode formation step (step S5), a source electrode 206 is formed in a selective region on the first main-surface side of the semiconductor wafer 106 by a sputtering apparatus (not shown) or the like. As the electrode material, for example, nickel or the like is conceivable. In addition, in order to reduce the contact resistance in this step, it is desirable to perform heat treatment and silicide.

As shown in FIGS. 9F and 10, in the first main-surface side protective-film formation step (step S6), the protective layer 207 is formed on the first main surface side of the semiconductor wafer 106.

As shown in FIGS. 9G and 10, in the second main-surface side grinding step (step S7), the semiconductor wafer 106 is turned upside down, the protective layer 207 on the first main-surface side of the semiconductor wafer 106 is adsorbed by a stage of a grinding apparatus (not shown), and the second main-surface side of the semiconductor wafer 106 is ground so that the thickness of the drift layer is 50 μm or more and 350 μm or less. At this time, in order to prevent the terminal portion of the second main surface of the semiconductor wafer 106 from having a sharp shape, it is necessary to adjust the shape of the terminal portion in advance. In order to perform the adjustment, it is necessary to process the terminal portion to some extent. Accordingly, the semiconductor wafer 106 having a diameter of 200 mm may become, for example, the semiconductor wafer 107 having a diameter of 199 mm or more and 200 mm or less, or the semiconductor wafer 108 having a diameter of 198 mm or more and 199 mm or less. Since a damaged layer remains in the surface layer on the second main-surface side of the ground semiconductor wafer 107 or 108, the damaged layer may be removed by etching.

As shown in FIGS. 9H and 10, in the second main-surface side drain-electrode formation step (step S8), a drain electrode 208 is formed.

As shown in FIGS. 9I and 10, in the first main-surface side protective-film removal step (step S9), the protective layer 207 formed on the first main-surface side of the semiconductor wafer 106 (or the semiconductor wafer 107 or 108) is removed. Depending on the material of the protective layer 207, when the heat-resistant temperature is lower than the raised temperature in the second main-surface side drain-electrode formation step (step S8), the order of steps S7 and S8 needs to be interchanged. Through the above steps, a semiconductor element is formed in the semiconductor wafer 106 (or the semiconductor wafer 107 or 108).

As shown in FIG. 10, in the dicing step (step S10), the semiconductor wafer 106 (or the semiconductor wafer 107 or 108) is divided into respective semiconductor elements.

It should be noted that the steps from the first main-surface side p-type region formation step (step S2) to the first main-surface side protective-film removal step (step S9) correspond to a wafer processing step of forming a semiconductor element by processing the semiconductor wafer in a state where the semiconductor wafer is stored in the transport container 100. In addition, also in the second to fourth preferred embodiments to be described below, the method of manufacturing a semiconductor element is the same as that in the first preferred embodiment, and thus description thereof is omitted.

### Effects

As described above, in the first preferred embodiment, the transport container 100 includes a housing 104 having an opening 104a through which the semiconductor wafer 106, 107, or 108 can be taken in and out from the Y-direction, a pair of thresholds 101 disposed in the housing 104 and supporting the back surface of the circumferential edge portion of the semiconductor wafer 106, 107, or 108 in the −X-direction intersecting the Y-direction and the X-direction opposite to the −X-direction, a lid 105 capable of opening and closing the opening 104a, and a retainer 110 fixed to the inner surface of the lid 105 and holding the end face of the semiconductor wafer 106, 107, or 108 in the Y-direction. The retainer 110 includes a fixing portion 111 fixed to the inner surface of the lid 105, and a left-wing portion 112a and a right-wing portion 112b respectively extending from the fixing portion 111 to the left and right and having elastic force, and the left-wing portion 112a and the right-wing portion 112b hold the end face of the semiconductor wafer 106, 107, or 108 by the elastic force.

Therefore, in a state where the back surface of the circumferential edge portion of the semiconductor wafer 106, 107, or 108 is supported by the pair of thresholds 101, applying force in a direction toward the center O of the semiconductor wafer 106, 107, or 108 by the left-wing portion 112a and the right-wing portion 112b to hold the semiconductor wafer 106, 107, or 108 makes it possible to apply force in a direction toward the center O of the semiconductor wafer 106, 107, or 108 to hold even the thinned semiconductor wafer 107 or 108 and the semiconductor wafer 107 or 108 having a smaller diameter. Therefore, the thinned semiconductor wafer 107 or 108 and the semiconductor wafers 106, 107, and 108 having different diameters can be uniformly held.

In addition, the angle 113 formed between a perpendicular line extending from the center O of the semiconductor wafer 106, 107, or 108 to the fixing portion 111 and a line from a contact point where the retainer 110 and the semiconductor wafer 106, 107, or 108 are in contact with each other toward the center O of the semiconductor wafer 106, 107, or 108 is 80 degrees or less.

Therefore, even when the diameters of the semiconductor wafers 106, 107, and 108 are different, it is possible to apply uniform holding force to the semiconductor wafer 106, 107, or 108 only by changing the positions of the two points where the semiconductor wafer 106, 107, or 108 is in contact with the retainer 110.

In addition, the angle 113 formed between a perpendicular line extending from the center O of the semiconductor wafer 106, 107, or 108 to the fixing portion 111 and a line from a contact point where the retainer 110 and the semiconductor wafer 106, 107, or 108 are in contact with each other toward the center O of the semiconductor wafer 106, 107, or 108 is 45 degrees. The left-wing portion 112a and the right-wing portion 112b hold the semiconductor wafer 106, 107, or 108 in point contact.

Therefore, since the semiconductor wafer 106, 107, or 108 can be uniformly held in the direction of the center O by the retainer 110, the semiconductor wafer 106, 107, or 108 can be maintained at an appropriate position.

In addition, since the retainer 110 is detachable from the lid 105, a retainer 110 that holds the semiconductor wafers 106, 107, and 108 having different diameters with a more appropriate force can be selected and exchanged. However, when the fixing portion 111 and the left-wing portion 112a and right-wing portion 112b are integrated, the entire retainer 110 can be exchanged, but when the fixing portion 111 and the left-wing portion 112a and right-wing portion 112b are separated, only the left-wing portion 112a and right-wing portion 112b can also be exchanged. In addition, when the semiconductor material of the semiconductor wafer 106, 107, or 108 is hard SiC, it is possible to obtain an effect that the retainer 110 is easily exchanged when the retainer 110 is deteriorated due to friction with the semiconductor wafer 106, 107, or 108.

In addition, the holding force when the semiconductor wafer 106, 107, or 108 is held in the left-wing portion 112a and the right-wing portion 112b is larger than 0 N and 2 N or less. Therefore, it is possible to prevent the semiconductor wafer 106, 107, or 108 from being deformed or broken when the semiconductor wafer 106, 107, or 108 is stored.

In addition, the method of manufacturing a semiconductor element includes: a wafer preparation step of placing the semiconductor wafer 106, 107, or 108 on a pair of thresholds 101, and then closing the lid 105 and holding the end face of the semiconductor wafer 106, 107, or 108 by the retainer 110 to store the semiconductor wafer 106, 107, or 108 in the transport container 100; and a wafer processing step of forming a semiconductor element by processing the semiconductor wafer 106, 107, or 108 in a state where the semiconductor wafer 106, 107, or 108 is stored in the transport container 100.

Therefore, in the manufacturing step of the semiconductor element, the transport container 100 can hold the thinned semiconductor wafer 107 or 108 and the semiconductor wafers 106, 107, and 108 having different diameters without being deformed or broken.

### Second Preferred Embodiment

Next, a second preferred embodiment will be described. FIG. 11 is an enlarged top view of a retainer 110 included in the transport container 100 according to the second preferred embodiment. It should be noted that in the second preferred embodiment, the same components as those described in the first preferred embodiment are denoted by the same reference numerals, and their description will be omitted.

As shown in FIG. 11, in the second preferred embodiment, a cushion material 118 having conductivity is provided on the surface on the side holding the semiconductor wafer 106, 107, or 108 in the left-wing portion 112a and the right-wing portion 112b. It should be noted that a conductive coating (not shown) may be applied instead of the cushion material 118. In addition, the configuration of the second preferred embodiment can also be adopted in the third and fourth preferred embodiments described below.

As described above, in the second preferred embodiment, a cushion material 118 having conductivity is provided or a coating having conductivity is applied on the surface on the side holding the semiconductor wafer 106, 107, or 108 in the left-wing portion 112a and the right-wing portion 112b.

Therefore, when the semiconductor wafer 106, 107, or 108 is stored, it is possible to suppress positional displacement of the semiconductor wafer 106, 107, or 108 and to mitigate contact damage. Furthermore, by suppressing electrostatic charging of the semiconductor wafer 106, 107, or 108, the influence of electrostatic charging on the semiconductor element formed on the semiconductor wafer 106, 107, or 108 can be suppressed.

### Third Preferred Embodiment

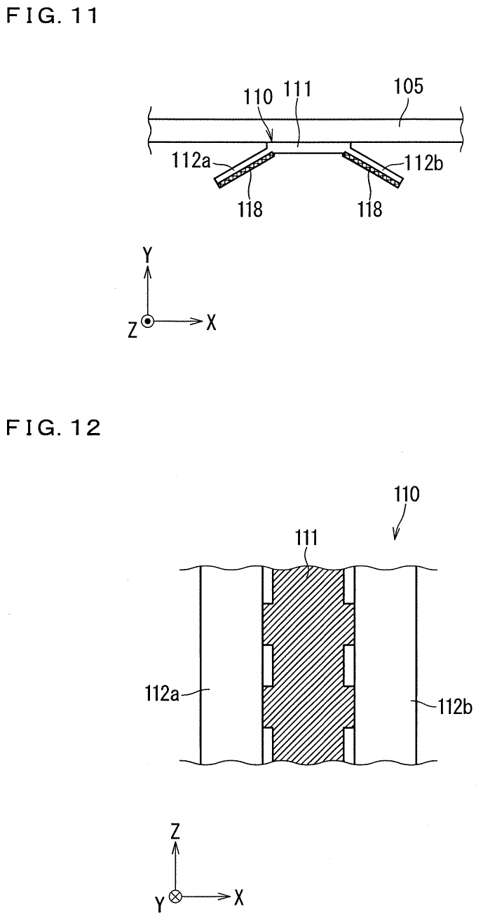

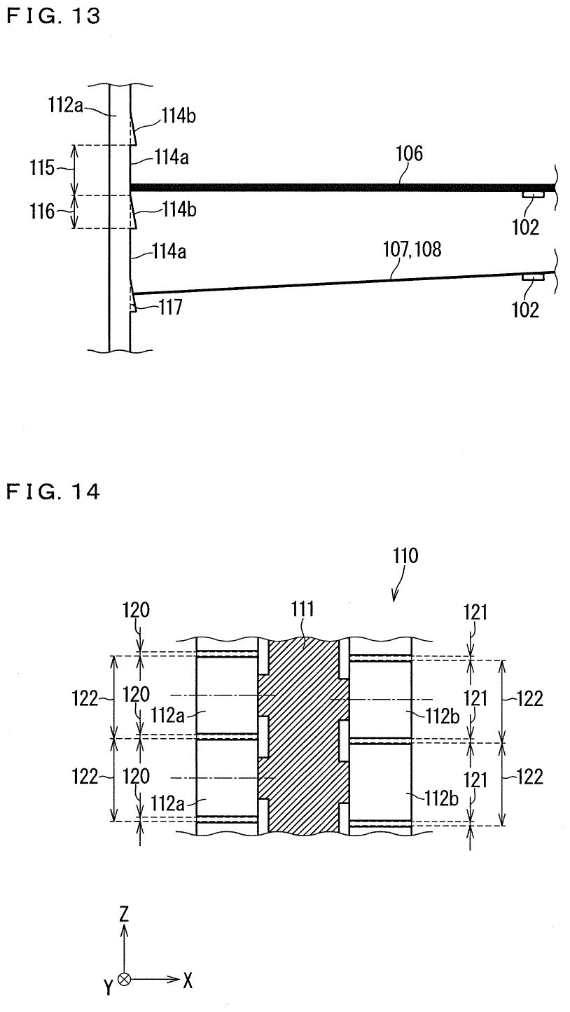

Next, a third preferred embodiment will be described. FIG. 12 is a view of the retainer 110 included in the transport container 100 according to the third preferred embodiment as viewed from the −Y-direction. FIG. 13 is a cross-sectional view of the left-wing portion 112a of the retainer 112 and its periphery. It should be noted that in the third preferred embodiment, the same components as those described in the first and second preferred embodiments are denoted by the same reference numerals, and their description will be omitted.

As described in the first preferred embodiment, the left-wing portion 112a and the right-wing portion 112b are configured to be able to hold up to 25 semiconductor wafers 106, 107, and 108 arranged along the vertical direction (Z-axis direction). As shown in FIGS. 12 and 13, in the third preferred embodiment, both the left-wing portion 112a and the right-wing portion 112b have a structure in which a vertical portion 114a parallel to the vertical direction (Z-axis direction) and an inclined portion 114b inclined toward the center O side of the semiconductor wafer 106, 107, or 108 with respect to the vertical portion 114a are repeated along the vertical direction (Z-axis direction).

The ratio of the length 115 of the vertical portion 114a and the length 116 of the inclined portion 114b can be optionally set, but the length 115 of the vertical portion 114a is desirably about 6 mm, the length 116 of the inclined portion 114b is desirably about 4 mm, and the total of the length 115 of the vertical portion 114a and the length 116 of the inclined portion 114b is set to 10 mm. In addition, the inclination angle 117 of the inclined portion 114b can also be optionally set, but is desirably in a range of about 0 degrees or more and 4 degrees or less.

As described above, in the third preferred embodiment, the left-wing portion 112a and the right-wing portion 112b hold a plurality of semiconductor wafers 106, 107, and 108 arranged along the vertical direction (Z-axis direction). Both the left-wing portion 112a and the right-wing portion 112b have a structure in which a vertical portion 114a and an inclined portion 114b inclined toward the center O side of the semiconductor wafer 106, 107, or 108 with respect to the vertical portion 114a are repeated along the vertical direction (Z-axis direction).

Therefore, even when the semiconductor wafer 106, 107, or 108 is deflected, the end face of the semiconductor wafer 106, 107, or 108 can be supported at either the vertical portion 114a or the inclined portion 114b, and the thinned and likely-to-be broken semiconductor wafer 107 or 108 can be prevented from being deformed or broken.

### Fourth Preferred Embodiment

Next, a fourth preferred embodiment will be described. FIG. 14 is a view of the retainer 110 included in the transport container 100 according to the fourth preferred embodiment as viewed from the −Y-direction. It should be noted that in the fourth preferred embodiment, the same components as those described in the first to third preferred embodiments are denoted by the same reference numerals, and their description will be omitted.

As shown in FIG. 14, in the fourth preferred embodiment, the retainer 110 includes a plurality of left-wing portions 112a and right-wing portions 112b provided along the vertical direction (Z-axis direction). Specifically, 25 left-wing portions 112a and 25 right-wing portions 112b are provided in the vertical direction (Z-axis direction). One semiconductor wafer is held for each left-wing portion 112a and each right-wing portion 112b, and a gap 120 between a left-wing portion 112a and another adjacent left-wing portion 112a and a gap 121 between a right-wing portion 112b and another adjacent right-wing portion 112b do not overlap each other in side view.

The length 122 of the left-wing portion 112a and right-wing portion 112b and the length of the gap 120 or 121 can be optionally set, but the length 122 of the left-wing portion 112a and right-wing portion 112b is desirably larger than 9.5 mm and smaller than 10 mm. In addition, the length of the gap 120 or 121 is desirably larger than 0 mm and smaller than 0.5 mm. Furthermore, the total of the length 122 of the left-wing portion 112a and right-wing portion 112b and the length of the gap 120 or 121 is set to 10 mm.

As described above, in the fourth preferred embodiment, the retainer 110 includes a plurality of left-wing portions 112a and right-wing portions 112b provided along the vertical direction (Z-axis direction), holds one semiconductor wafer for each left-wing portion 112a and each right-wing portion 112b, and the gap 120 between a left-wing portion 112a and another adjacent left-wing portion 112a and the gap 121 between a right-wing portion 112b and another adjacent right-wing portion 112b do not overlap each other in side view.

Therefore, by holding the semiconductor wafers one by one, even when the semiconductor wafers 106, 107, and 108 having different diameters are mixed, each semiconductor wafer can be held. In addition, by causing the left and right gaps 120 and 121 not to overlap in a side view, it is possible to prevent the thinned semiconductor wafer 107 or 108 from being sandwiched in the gap 120 or 121.

It should be noted that each preferred embodiment can be freely combined, and each preferred embodiment can be appropriately modified or omitted.

Hereinafter, various aspects of the present disclosure will be collectively described as appendixes.

### (Appendix 1)

A transport container for a semiconductor wafer, comprising:
a housing having an opening through which a semiconductor wafer is configured to be taken in and out from a first direction;
a pair of thresholds disposed in the housing, the pair of thresholds configured to support a back surface of a circumferential edge portion of the semiconductor wafer in a second direction intersecting the first direction and a third direction opposite to the second direction;
a lid configured to open and close the opening; and
a retainer fixed to an inner surface of the lid, the retainer configured to hold an end face of the semiconductor wafer in the first direction, wherein
the retainer includes a fixing portion fixed to the inner surface of the lid, and a left-wing portion and a right-wing portion respectively extending to left and right from the fixing portion and having elastic force, and
the left-wing portion and the right-wing portion hold the end face of the semiconductor wafer by the elastic force.

### (Appendix 2)

The transport container for a semiconductor wafer according to appendix 1, wherein an angle formed between a perpendicular line extending from a center of the semiconductor wafer to the fixing portion and a line from a contact point at which the retainer is in contact with the semiconductor wafer toward the center of the semiconductor wafer is 80 degrees or less.

### (Appendix 3)

The transport container for a semiconductor wafer according to appendix 2, wherein
the angle formed between the perpendicular line extending from the center of the semiconductor wafer to the fixing portion and the line from the contact point at which the retainer is in contact with the semiconductor wafer toward the center of the semiconductor wafer is 45 degrees, and
the left-wing portion and the right-wing portion hold the semiconductor wafer in point contact.

### (Appendix 4)

The transport container for a semiconductor wafer according to any one of appendixes 1 to 3, wherein the retainer is detachable from the lid.

### (Appendix 5)

The transport container for a semiconductor wafer according to any one of appendixes 1 to 4, wherein a holding force when the semiconductor wafer is held in the left-wing portion and the right-wing portion is larger than 0 N and 2 N or less.

### (Appendix 6)

The transport container for a semiconductor wafer according to any one of appendixes 1 to 5, wherein a surface on a side holding the semiconductor wafer in each of the left-wing portion and the right-wing portion is provided with a cushion material having conductivity, or is coated with a coating having the conductivity.

### (Appendix 7)

The transport container for a semiconductor wafer according to any one of appendixes 1 to 6, wherein
the left-wing portion and the right-wing portion hold a plurality of the semiconductor wafers arranged along a vertical direction, and
both the left-wing portion and the right-wing portion have a structure in which a vertical portion and an inclined portion inclined toward a center side of the semiconductor wafer with respect to the vertical portion are repeated along the vertical direction.

### (Appendix 8)

The transport container for a semiconductor wafer according to any one of appendixes 1 to 6, wherein
the retainer includes a plurality of the left-wing portions and the right-wing portions provided along a vertical direction,
one of the semiconductor wafers is held for each of the left-wing portions and each of the right-wing portions, and
a gap between the left-wing portion and the other adjacent left-wing portion and a gap between the right-wing portion and the other adjacent right-wing portion do not overlap with each other in a side view.

### (Appendix 9)

A method of manufacturing a semiconductor element using the transport container for a semiconductor wafer according to any one of appendixes 1 to 8, the method comprising:
a wafer preparation step of placing the semiconductor wafer on the pair of thresholds, and then closing the lid to hold the end face of the semiconductor wafer with the retainer to store the semiconductor wafer in the transport container; and
a wafer processing step of processing the semiconductor wafer in a state where the semiconductor wafer is stored in the transport container to form the semiconductor element.

While the disclosure has been shown and described in detail, the foregoing description is in all aspects illustrative and not restrictive. It is therefore understood that numerous modifications and variations can be devised.

What is claimed is:

1. A transport container for a semiconductor wafer, comprising:
a housing having an opening through which a semiconductor wafer is configured to be taken in and out from a first direction;
a pair of thresholds disposed in the housing, the pair of thresholds configured to support a back surface of a circumferential edge portion of the semiconductor wafer in a second direction intersecting the first direction and a third direction opposite to the second direction;
a lid configured to open and close the opening; and
a retainer fixed to an inner surface of the lid, the retainer configured to hold an end face of the semiconductor wafer in the first direction, wherein
the retainer includes a fixing portion fixed to the inner surface of the lid, and a left-wing portion and a right-wing portion respectively extending to left and right from the fixing portion and having elastic force, and
the left-wing portion and the right-wing portion hold the end face of the semiconductor wafer by the elastic force.

2. The transport container for a semiconductor wafer according to claim 1, wherein an angle formed between a perpendicular line extending from a center of the semiconductor wafer to the fixing portion and a line from a contact point at which the retainer is in contact with the semiconductor wafer toward the center of the semiconductor wafer is 80 degrees or less.

3. The transport container for a semiconductor wafer according to claim 2, wherein
the angle formed between the perpendicular line extending from the center of the semiconductor wafer to the fixing portion and the line from the contact point at which the retainer is in contact with the semiconductor wafer toward the center of the semiconductor wafer is 45 degrees, and
the left-wing portion and the right-wing portion hold the semiconductor wafer in point contact.

4. The transport container for a semiconductor wafer according to claim 1, wherein the retainer is detachable from the lid.

5. The transport container for a semiconductor wafer according to claim 1, wherein a holding force when the semiconductor wafer is held in the left-wing portion and the right-wing portion is larger than 0 N and 2 N or less.

6. The transport container for a semiconductor wafer according to claim 1, wherein a surface on a side holding the semiconductor wafer in each of the left-wing portion and the right-wing portion is provided with a cushion material having conductivity, or is coated with a coating having the conductivity.

7. The transport container for a semiconductor wafer according to claim 1, wherein
the left-wing portion and the right-wing portion hold a plurality of the semiconductor wafers arranged along a vertical direction, and
both the left-wing portion and the right-wing portion have a structure in which a vertical portion and an inclined portion inclined toward a center side of the semiconductor wafer with respect to the vertical portion are repeated along the vertical direction.

8. The transport container for a semiconductor wafer according to claim 1, wherein
the retainer includes a plurality of the left-wing portions and the right-wing portions provided along a vertical direction,
one of the semiconductor wafers is held for each of the left-wing portions and each of the right-wing portions, and
a gap between the left-wing portion and the other adjacent left-wing portion and a gap between the right-wing portion and the other adjacent right-wing portion do not overlap with each other in a side view.

9. A method of manufacturing a semiconductor element using the transport container for a semiconductor wafer according to claim 1, the method comprising:
a wafer preparation step of placing the semiconductor wafer on the pair of thresholds, and then closing the lid to hold the end face of the semiconductor wafer with the retainer to store the semiconductor wafer in the transport container; and
a wafer processing step of processing the semiconductor wafer in a state where the semiconductor wafer is stored in the transport container to form the semiconductor element.
